(19) United States
(12) Patent Application Publication
(10) Pub. No.: US 2016/0266213 A1
(43) Pub. Date: Sep. 15, 2016

(54) APPARATUS FOR DIAGNOSING FAULT OF BATTERY SYSTEM AND METHOD FOR THE SAME

(71) Applicants: HYUNDAI MOTOR COMPANY, Seoul (KR); Kia Motors Corporation, Seoul (KR)

(72) Inventor: Hyun KIM, Hwaseong-si (KR)

(21) Appl. No.: 14/822,746

(22) Filed: Aug. 10, 2015

(30) Foreign Application Priority Data
Mar. 11, 2015 (KR) 10-2015-0033550

(51) Int. Cl. G01R 31/36

(52) U.S. Cl. CPC G01R 31/3679; G01R 31/362

(57) ABSTRACT

A fault diagnosis apparatus for a battery system includes an alternator sensor for detecting a first voltage that is a generating voltage of an alternator. A battery sensor detects a second voltage that is a voltage of a battery. An engine control unit (ECU) is configured to receive the first voltage and the second voltage from the alternator sensor and the battery sensor, respectively, to calculate a difference value by subtracting the second voltage from the first voltage, and to diagnose a connection failure in a battery terminal or a fault attributable to battery performance degradation, based on the difference value and a diagnosis time.

### CROSS REFERENCE TO RELATED APPLICATION

The present application claims the benefit of priority to Korean Patent Application Number 10-2015-0033550 filed on Mar. 11, 2015, the entire content of which application is incorporated herein for all purposes by this reference.

### TECHNICAL FIELD

The present disclosure relates to an apparatus for diagnosing a fault of a battery system that can diagnose a battery charging failure using a generating voltage of an alternator and a voltage of a battery, and a method for the same.

### BACKGROUND

In general, a pulse width modulation (PWM) controlled alternator includes a signal line connected between the alternator and an engine control unit (ECU) through a wire, and generates electricity through analog waveform signal control. Here, the alternator and the ECU are connected with wires of an FR line and a C line. The FR line transmits a signal indicative of a state of power generation inside the alternator to the ECU. The C line transmits a signal for power generation from the ECU to the alternator. The alternator is connected to a battery via a B+ terminal, and the battery is charged using energy generated by the alternator. When a voltage of the battery decreases due to a charging failure, a warning light indicating the battery charging failure is illuminated on an instrument cluster.

The existing PWM controlled alternator is controlled by a C terminal and an FR terminal. The ECU controls a target voltage to be generated by the alternator using an ON/OFF ratio through the C terminal, and may check an exciting current of the alternator through the FR terminal.

However, as the ECU receives limited information from the alternator, it is difficult to precisely control the alternator according to the characteristics of power generation of the alternator. Further, diagnosis of a battery charging system is difficult and inaccurate.

Additionally, since failure in connection between the alternator and a battery terminal or charging failure attributable to battery performance degradation may not be distinguished from alternator malfunction, the alternator may be unnecessarily replaced thus causing high expense.

The foregoing is intended merely to aid in the understanding of the background of the present disclosure, and is not intended to mean that the present disclosure falls within the purview of the related art that is already known to those skilled in the art.

### SUMMARY

The present disclosure has been made keeping in mind the above problems occurring in the related art. An aspect of the present inventive concept provides an apparatus for diagnosing a fault of a battery system that can diagnose a connection failure in a battery terminal or a fault attributable to battery performance degradation, using a generating voltage of an alternator and a voltage of a battery and a method for the same.

An apparatus for diagnosing a fault of a battery system according to the present disclosure may include an alternator sensor for detecting a first voltage that is a generating voltage of an alternator. A battery sensor detects a second voltage that is a voltage of a battery. An engine control unit (ECU) is configured to receive the first voltage and the second voltage from the alternator sensor and the battery sensor, respectively, to calculate a difference value subtracting the second voltage from the first voltage, and to diagnose a connection failure in a battery terminal or a fault attributable to battery performance degradation, based on the difference value and a diagnosis time.

The ECU communicates with the alternator sensor and the battery sensor through local interconnect network (LIN) communication.

The ECU determines whether the difference value is greater than a reference value, and whether the diagnosis time is longer than a reference time.

The ECU diagnoses the connection failure in the battery terminal or the fault attributable to the battery performance degradation when the difference value is greater than the reference value and the diagnosis time is longer than the reference time.

The predetermined value is 0.5 V.

The ECU receives the first voltage and the second voltage when an engine is ON.

The ECU receives the first voltage and the second voltage when LIN communication operates normally.

A method for diagnosing a fault of a battery system may include determining, by an ECU, whether an engine is ON. The ECU determines whether LIN communication operates normally. An alternator sensor detects a first voltage which is a generating voltage of an alternator. A battery sensor detects a second voltage which is a voltage of a battery. A difference value is calculated by subtracting the second voltage from the first voltage.

According to the apparatus and method for diagnosing a fault of a battery system as described above, a connection failure in a battery terminal or a fault attributable to battery performance degradation may be distinguished from alternator malfunction, thus preventing unnecessary replacement of the expensive alternator.

Further, by using the characteristics of a LIN controlled alternator, the connection failure in the battery terminal or the fault attributable to battery performance degradation may be effectively diagnosed.

### BRIEF DESCRIPTION OF THE DRAWINGS

The above and other objects, features and other advantages of the present disclosure will be more clearly understood from the following detailed description taken in conjunction with the accompanying drawings.

FIG. 1 is a block diagram illustrating an apparatus for diagnosing a fault of a battery system according to an embodiment of the present inventive concept.

FIG. 2 is a flow diagram illustrating a method for diagnosing a fault of a battery system according to an embodiment of the present inventive concept.

### DETAILED DESCRIPTION OF THE EMBODIMENTS

Hereinafter, a fault diagnosis apparatus and method for a battery system according to an embodiment of the present inventive concept is described referring to the accompanying drawings.

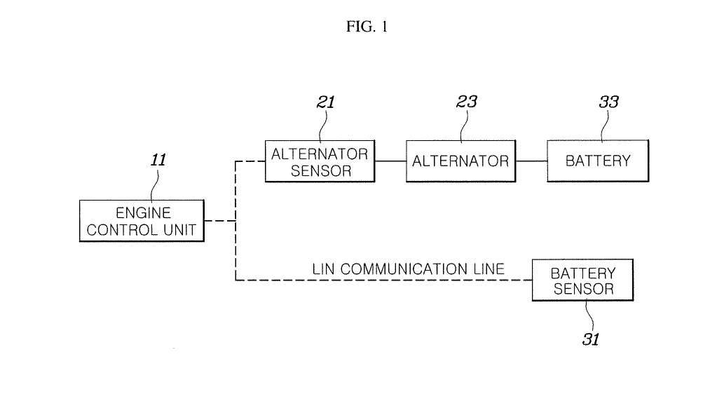

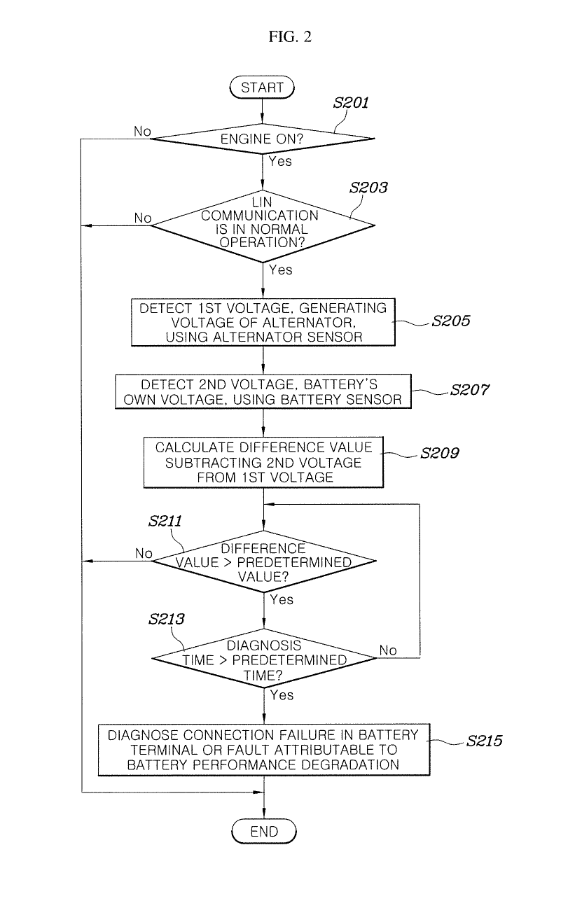

FIG. 1 is a block diagram illustrating an apparatus for diagnosing a fault of a battery system according to an embodiment of the present inventive concept, and FIG. 2 is a flow diagram illustrating a method for diagnosing a fault of a battery system according to an embodiment of the present inventive concept.

Referring to FIG. 1, an apparatus for diagnosing a fault of a battery system may include an alternator sensor 21 for detecting a first voltage that is a generating voltage of an alternator 23. A battery sensor 31 detects a second voltage that is a voltage of a battery 33. An engine control unit (ECU) 11 is configured to receive the first voltage and the second voltage from the alternator sensor 21 and the battery sensor 31, respectively, to calculate a difference value by subtracting the second voltage from the first voltage, and to diagnose a connection failure in a battery terminal or a fault attributable to battery performance degradation, based on the difference value and a diagnosis time.

The alternator 23 generates electricity using engine torque and charges the battery 33 using the generated electricity. Chip-type sensors are arranged in the alternator 23 for self-diagnosis, or to determine physical failure or electric failure, and the alternator sensor 21 may be included in the chip-type sensors. The alternator sensor 21 detects a voltage of electricity generated by the alternator 23.

A voltage of electricity charged in the battery 33 increases with power generation of the alternator 23, and the battery sensor 31 is arranged to measure the voltage of the electricity charged in the battery 33.

In this case, the alternator 23 is connected to the battery 33 via a B+ terminal to deliver the generated electricity to the battery 33. When the connection in the B+ terminal fails, the voltage of electricity generated by the alternator 23 is different from the voltage of the battery 33, measured by the battery sensor 31. In other words, when the alternator 23 is not connected to the battery 33 via the B+ terminal, even though the alternator 23 generates electricity, the generated electricity is not be delivered to the battery 33 and the battery 33 is not charged. Accordingly, the voltage of the battery 33, detected by the battery sensor 31, is less than the generated voltage detected by the alternator sensor 21.

When the battery 33 is degraded due to deterioration or malfunction, the voltage of electricity generated by the alternator 23 is different from the measured voltage of the battery 33. In other words, although the alternator 23 generates electricity, as charging does not effectively progress due to performance degradation of the battery 33, the voltage of the battery 33 measured by the battery sensor 31 is less than the generating voltage of the alternator 23, which is detected by the alternator sensor 21.

Consequently, the ECU 11 may determine the B+ terminal connection failure between the alternator 23 and the battery 33, or the fault attributable to the battery performance degradation, by receiving the first voltage and the second voltage, respectively sensed from the alternator sensor 21 and the battery sensor 31, and by calculating the difference value between the first voltage and the second voltage.

On the other hand, the ECU 11 communicates with the alternator sensor 21 and the battery sensor 31 using local interconnect network (LIN) communication.

In other words, the alternator sensor 21 detects the first voltage, which is a voltage of electricity generated by the alternator 23, and outputs the first voltage to the ECU 11 through a LIN communication line. The battery sensor 31 detects the second voltage, which is a voltage of the battery 33, and outputs the second voltage to the ECU 11 through a LIN communication line.

When the existing pulse width modulation (PWM) controlled alternator, the ECU 11 receives very limited information from the alternator 23. Therefore, it is difficult to precisely control the alternator according to the characteristics of power generation of the alternator 23. Further, diagnosis of a battery charging system is difficult and inaccurate. However, as the present disclosure applies the LIN controlled alternator 23, it is possible to accurately diagnose connection failure in a battery terminal or a fault attributable to battery performance degradation, using the difference value by subtracting the second voltage from the first voltage.

Here, the ECU 11 determines whether the difference value is greater than a reference value, and whether a diagnosis time is longer than a reference time.

When the difference value is greater than the reference value and the diagnosis time is longer than the reference time, the ECU 110 may diagnose a connection failure in a battery terminal or a fault attributable to the battery performance degradation.

In this case, the reference value is set to a value capable of determining whether charging of the battery 33 smoothly progress. Typically, the value may be set to be around 0.5 V. However, as the value can be different depending on a vehicle model, it is desirable to optimize the value by testing a vehicle.

When the difference value obtained by subtracting the second voltage, which is the voltage of the battery 33, from the first voltage, which is the generating voltage of the alternator 23, is less than the reference value, the battery 33 is effectively charged by the alternator 23, and thus fault diagnosis is not necessary. When the difference value is greater than the reference value, it is determined that charging of the battery 33 is not progressing smoothly regardless of power generation of the alternator 23.

When the battery 33 is completely discharged at the beginning of charging, the difference value may be greater than the reference value. Therefore, it is necessary to determine whether the diagnosis time is longer than the reference time after comparing the difference value with the reference value.

Here, the diagnosis time can be set to one selected from among the duration from the beginning of power generation of the alternator 23, the duration from when receiving the first and second voltage, or the duration from when the difference is determined to be greater than the reference value. The diagnosis time may be variable set according to the designer's determination. In addition, the reference time is a time for which the battery 33 is sufficiently charged by the alternator 23. The reference time can be set to a minimum of 1 minute to prevent an error, but it is desirable that the designer sets the time to be optimized according to a vehicle model.

That is, after detecting whether the diagnosis time is longer than the reference time in order to consider that the difference value can be measured to be greater than the reference value due to the discharged state of the battery 33 at the beginning of power generation of the alternator 23, if the diagnosis time is longer than the reference time, it may be determined that charging of the battery 33 is not smoothly progressing though power generation of the alternator 23 has continued for the reference time. Therefore, the ECU 11 may diagnose a connection failure in a battery terminal or a fault attributable to battery performance degradation.

When the difference value obtained by subtracting the second voltage from the first voltage is greater than the reference value but the diagnosis time is the same or less than the reference time, it is determined that the battery 33 is not sufficiently charged by the alternator 23. Accordingly, the difference can be compared with the reference value again, rather than performing the fault diagnosis.

As described above, when the connection failure in the battery terminal or the fault attributable to battery performance degradation is diagnosed, the ECU 11 may output a code relating to the fault. Then, a mechanic can detect the fault according to the code and quickly adjust the connection in the battery terminal or replace the battery, thus preventing unnecessary replacement of the alternator 23.

The ECU 11 receives the first voltage and the second voltage when an engine is turned ON or when LIN communication operates normally.

That is, the ECU 11 performs diagnosis control when the engine is turned ON and the alternator 23 generates electricity. If the engine is OFF, the alternator 23 cannot generate electricity, and thus, diagnosis control of the present disclosure is not necessary.

Further, the diagnosis control is performed when the alternator sensor 21 and the battery sensor 31 communicate using the LIN communication. Whether the LIN communication operates normally is determined by LIN communication signals of the alternator sensor 21 and the battery sensor 31, which are received from the ECU 11. If the LIN communication is not available, reliability of the LIN communication signals decreases, and thus the diagnosis control cannot be performed.

As described above, the diagnosis control is performed after the ECU 11 determines that the engine is turned ON and LIN communication operates normally, before receiving the first voltage and the second voltage. Therefore, the reliability of the diagnosis increases in case of the connection failure in the battery terminal or in case of the fault attributable to the battery performance degradation.

FIG. 2 illustrates a method for diagnosing a fault of a battery system according to an embodiment of the present inventive concept.

The method may include determining, by the ECU 11, whether an engine is turned ON (S201). The ECU 11 determines whether LIN communication operates normally (S203). A first voltage, which is a generating voltage of the alternator 23, is detected using the alternator sensor 21 when the engine is turned ON and the LIN communication operates normally (S205). A second voltage, which is a voltage of the battery 33, is detected using the battery sensor 31 (S207). A difference value is calculated by subtracting the second voltage from the first voltage (S209). Whether the difference value is greater than a reference value is determined (S211). Whether a diagnosis time is longer than a reference time is determined when the difference value is greater than the reference value (S213). A fault signal is output when there is a connection failure in a battery terminal and a fault attributable to performance degradation of the battery 33 when the diagnosis time is longer than the reference time (S215).

According to the apparatus for diagnosing a fault of a battery system as described above, a connection failure in a battery terminal or a fault attributable to battery performance degradation may be distinguished from alternator malfunction, whereby it is possible to prevent unnecessary replacement of the expensive alternator.

Further, using the characteristics of a LIN controlled alternator, the connection failure in the battery terminal or the fault attributable to battery performance degradation may be effectively diagnosed.

Although the exemplary embodiments of the present inventive concept have been disclosed for illustrative purposes, those skilled in the art will appreciate that various modifications, additions, and substitutions are possible, without departing from the scope and spirit of the invention as disclosed in the accompanying claims.

What is claimed is:

1. An apparatus for diagnosing a fault of a battery system, comprising:
an alternator sensor detecting a first voltage that is a generating voltage of an alternator;
a battery sensor detecting a second voltage that is a voltage of a battery; and
an engine control unit (ECU) configured to receive the first voltage and the second voltage from the alternator sensor and the battery sensor, respectively, to calculate a difference value by subtracting the second voltage from the first voltage, and to diagnose a connection failure in a battery terminal or a fault attributable to battery performance degradation, based on the difference value and a diagnosis time.

2. The apparatus of claim 1, wherein the ECU communicates with the alternator sensor and the battery sensor through local interconnect network (LIN) communication.

3. The apparatus of claim 1, wherein the ECU determines whether the difference value is greater than a reference value, and whether the diagnosis time is longer than a reference time.

4. The apparatus of claim 3, wherein the ECU diagnoses the connection failure in the battery terminal or the fault attributable to the battery performance degradation when the difference value is greater than the reference value and the diagnosis time is longer than the reference time.

5. The apparatus of claim 3, wherein the reference value is 0.5 V.

6. The apparatus of claim 1, wherein the ECU receives the first voltage and the second voltage when an engine is ON.

7. The apparatus of claim 1, wherein the ECU receives the first voltage and the second voltage when the LIN communication operates normally.

8. A method for diagnosing a fault of a battery system, comprising steps of:
determining, by an ECU, whether an engine is ON;
determining, by the ECU, whether LIN communication operates normally;
detecting, by an alternator sensor, a first voltage which is a generating voltage of an alternator;
detecting, by a battery sensor, a second voltage which is a voltage of a battery; and
calculating a difference value by subtracting the second voltage from the first voltage.

9. The method according to claim 8, further comprising steps of:
determining whether the difference value is greater than a reference value;
determining whether a diagnosis period time is longer than a reference time when the difference value is greater than the reference value; and
outputting a fault signal when the diagnosis time is longer than the reference time.
